(19) United States
(12) Patent Application Publication
(10) Pub. No.: US 2023/0036698 A1
(43) Pub. Date: Feb. 2, 2023

(54) REVERSE BLOCKING GALLIUM NITRIDE HIGH ELECTRON MOBILITY TRANSISTOR

(71) Applicants: University of Electronic Science and Technology of China, Chengdu (CN); Institute of Electronic and Information Engineering of UESTC in Guangdong, Dongguan (CN)

(72) Inventors: Ruize SUN, Chengdu (CN); Wanjun CHEN, Chengdu (CN); Chao LIU, Chengdu (CN); Pan LUO, Chengdu (CN); Fangzhou WANG, Chengdu (CN)

(73) Assignees: University of Electronic Science and Technology of China, Chengdu (CN); Institute of Electronic and Information Engineering of UESTC in Guangdong, Dongguan (CN)

(21) Appl. No.: 17/876,582

(22) Filed: Jul. 29, 2022

(30) Foreign Application Priority Data
Jul. 30, 2021 (CN) 202110868565.1

(51) Int. Cl. H01L 29/20; H01L 29/66; H01L 29/778; H01L 29/06

(52) U.S. Cl. CPC H01L 29/2003; H01L 29/0611; H01L 29/7786; H01L 29/66462

(57) ABSTRACT

A reverse blocking gallium nitride (GaN) high electron mobility transistor includes, sequentially stacked from bottom to top, a substrate, a nucleation layer, a buffer layer, a barrier layer, a dielectric layer. The buffer layer and the barrier layer form a heterojunction structure. The barrier layer is provided with at least two p-GaN structures. The barrier layer is provided with a source metal at one end and a drain metal at the other end, source metal forms ohmic contact and drain metal forms Schottky contact with AlGaN barrier, respectively. In forward conduction, the two-dimensional electron gas below the spaced p-GaN structure connected to the drain metal is conductive, and a turn-on voltage of the device is low. During reverse blocking, the two-dimensional electron gas at the spaced p-GaN structure is rapidly depleted under reverse bias, to form a depletion region, so that the blocking capability of the device is improved.

### CROSS REFERENCE TO THE RELATED APPLICATIONS

This application is based upon and claims priority to Chinese Pat. Application No. 202110868565.1, filed on Jul. 30, 2021, the entire contents of which are incorporated herein by reference.

### TECHNICAL FIELD

The present invention pertains to the technical field of semiconductor power devices, in particular to a reverse blocking gallium nitride high electron mobility transistor

### BACKGROUND

In power electronics systems, there are two power conversion modes: AC-DC-AC converter and AC-AC converter, where AC-AC converter has the advantages of small size, low weight and high conversion efficiency, and is widely used in industrial equipment and household appliances. The reverse blocking power device is the core device of the AC-AC power converter.

With the development of society and science and technology, various industries have put forward stricter requirements on power conversion efficiency, volume, heat dissipation, stability and other aspects. Compared with conventional silicon (Si), gallium nitride (GaN) has a low relative dielectric constant, high critical breakdown electric field, high thermal conductivity and other material characteristics, which can better meet the needs of the industry. Therefore, it is of great significance to study the reverse blocking devices of GaN materials.

The GaN-based reverse blocking high electron mobility transistors (RB-HEMTs) with a Schottky drain structure has a high drain Schottky barrier in order to have strong reverse blocking capability, this structure will not only lead to large reverse leakage current, but also high forward turn-on voltage. Although the reverse blocking voltage is higher and the reverse leakage current is low by directly adopting a similar GaN-based enhancement-mode gate structure where a p-type GaN (p-GaN) structure or recessed MIS structure is used as a reverse blocking drain, the turn-on voltage is too large. Therefore, at present, GaN-based reverse blocking devices mostly adopt one p-GaN structure or a recessed MIS structure in front of the drain, which contacts Schottky to form a hybrid drain to improve the breakdown voltage, so as to achieve lower forward turn-on voltage and higher reverse breakdown voltage at the same time. However, in order to form a suitable forward turn-on voltage, the hybrid drain GaN-based reverse blocking device formed by the recessed MIS and Schottky needs to recess the barrier layer by etching, while the formation of hybrid drain structure composed of the p-GaN structure and Schottky needs to etch the drain p-GaN separately. The above two methods have the following problems:

Since the p-GaN layer and barrier layer are thin, the recess etching process alone is relatively complex, and the thickness of the barrier layer or p-GaN layer after etching has to be precisely controlled, which is more difficult to process and manufacture.

The existing p-GaN-Schottky hybrid drain structure requires etching the p-GaN layer twice, namely, forming the drain side p-GaN when forming the gate p-GaN structure and secondary recess etching the drain side p-GaN, see FIG. 1 and FIGS. 2 (a), it is difficult to etch p-GaN completely due to alignment deviation, see FIGS. 2 (b) and FIGS. 2 (c), which will lead to the forward turn-on voltage of the actually prepared device being greater than the voltage in the design simulation.

### SUMMARY

The present invention is intended to address the problem that the prior hybrid drain p-GaN RB-HEMTs, see FIG. 1, have complex hybrid drain process steps, the thickness of the grinding needs to be precisely controlled, and there are alignment errors for multiple recess etching, see FIG. 2. However, the drain of a simple Schottky or p-GaN rectifier structure suffers from low reverse blocking capability or high turn-on voltage. In response to the above problem, a p-GaN RB-HEMTs structure with hybrid drain formed by spaced p-GaN and Schottky is proposed. It is compatible with the existing GaN-based p-GaN enhancement-mode HEMTs process, and simultaneously achieves high reverse blocking capability and low forward turn-on voltage of the RB-HEMTs without increasing process steps and manufacturing difficulty. The structure provided by the present invention features that:

High reverse blocking capability and low forward turn-on voltage.

Simple process, where the spaced p-GaN structure and the gate p-GaN structure are formed synchronously.

High feasibility, where it avoids the recess etching of p-GaN layer or barrier layer by conventional p-GaN or recessed MIS hybrid drain structure, since the recess etching of barrier layer and p-GaN layer involves various issues such as precise control of etching thickness, etching damage, lithography alignment and so on.

The present invention is especially suitable for the preparation of high-power bidirectional switches.

To achieve the above purpose, the technical solution adopted by the present invention is as follows:

The GaN-based RB-HEMTs include, sequentially stacked from bottom to top, a substrate 1, a nucleation layer 2, a buffer layer 3, a channel layer 4 and a barrier layer 5, wherein the channel layer 4 and the barrier layer 5 form a heterojunction structure; two ends of an upper surface of the barrier layer 5 are respectively provided with a first metal 9 embedded in the barrier layer 5 to form an ohmic contact and being a drain and a second metal 10 embedded in the barrier layer 5 to form an ohmic contact and being a source; characterized in that a first p-GaN structure 7 is provided on a side of the upper surface of the barrier layer 5 close to the second metal 10, a second p-GaN structure 8 is provided on a side of the upper surface of the barrier layer 5 close to the first metal 9, and a dielectric layer 6 is provided between the second metal 10 and the first p-GaN structure 7, between the first p-GaN structure 7 and the second p-GaN structure 8, and between the second p-GaN structure 8 and the first metal 9; the second p-GaN structure 8 includes one or more p-GaN structures arranged side-by-side in a device longitudinal direction, a length of the provided p-GaN structure in the device longitudinal direction is lower than a length of the barrier layer 5 in the device longitudinal direction, each of the p-GaN structures is isolated by the dielectric layer 6; a direction from the source to the drain is defined as a device lateral direction, and the device longitudinal direction is a third dimension direction perpendicular to both the device lateral direction and the device vertical direction; an upper surface of the first p-GaN structure 7 is provided with a third metal 11, the third metal 11 completely covering the upper surface of the first p-GaN structure 7 and extending to cover a part of an upper surface of the dielectric layer 6 along two sides in the device lateral direction, and the third metal 11 being a gate; and the first metal 9 extends in a direction pointing to the second metal 10 along an upper surface of the second p-GaN structure 8 to completely cover the upper surface of the second p-GaN structure 8 and the part of the upper surface of the dielectric layer 6.

Further, the second p-GaN structure 8 includes a plurality of p-GaN structures configured in such a way that a single row of p-GaN structures are distributed side-by-side along the device longitudinal direction or multiple rows of p-GaN structures are alternatively distributed side-by-side along the device longitudinal direction in a staggered pattern.

The present invention has the beneficial effects that:

Simple process and high feasibility; the spaced p-GaN structure adopted by the present invention has a height identical with that of the gate p-GaN layer, is formed synchronously with the gate p-GaN structure, does not need to be recess etched separately, and the processing and preparation process is completely compatible with the conventional GaN-based p-GaN enhancement-mode HEMT. Therefore, compared with the existing recessed MIS or GaN-based HEMT with hybrid drain structure formed by the p-GaN and Schottky contact, the process is simpler and the fabrication feasibility is higher.

High breakdown voltage and low forward turn-on voltage. The present invention adopts a hybrid drain electrode composed of contact of spaced p-GaN structure and Schottky contact. During the forward conduction, the forward conduction voltage is extremely low because the electron gas below the spaced p-GaN structure is not depleted during the forward conduction. In reverse blocking, the channel electron gas below the gaps between the spaced p-GaN structure is easily depleted at low reverse bias voltage, which makes the device have high breakdown voltage and low breakage current.

### BRIEF DESCRIPTION OF DRAWINGS

FIG. 1 is a structural schematic diagram of a reverse blocking device with a recess etched p-GaN and Schottky connected hybrid drain in the prior art;

FIGS. 2A-2C show a p-GaN recess etching process in the prior art, where FIG. 2A is an ideal p-GaN recess etching condition, FIG. 2B shows a left alignment error, and FIG. 2C shows a right alignment error;

FIG. 3 is a 3D structural diagram of the RB-HEMTs in the present invention;

FIG. 4 is a 3D structural schematic diagram of the RB-HEMTs with multiple p-GaN structure arranged in parallel in the present invention;

FIGS. 5A-5D show a drain p-GaN structure of other shapes and corresponding arrangement according to the present invention, where FIG. 5A is a front view of the structure, FIG. 5B is a staggered arrangement of two rows of rectangular p-GaN structures, FIG. 5C is an arrangement of triangular p-GaN structures, and FIG. 5D is a hybrid arrangement of triangular and rhombic p-GaN structures;

FIGS. 6A-6C are structural schematic diagrams of etching a p-GaN layer and forming a gate p-GaN structure and a drain p-GaN structure at the same time during a preparation process of the RB-HEMTs in the present invention, where FIG. 6A is a schematic diagram of GaN wafer before etching, FIG. 6B is a front view after etching and forming the gate p-GaN structure and the drain p-GaN structure, and FIG. 6C is a top view after etching and forming the gate p-GaN structure and the drain p-GaN structure;

FIG. 7 is a comparison diagram of reverse blocking characteristics of the RB-HEMTs in the present invention and the Schottky barrier RB-HEMTs in the prior art; and

FIG. 8 is a comparison diagram of forward output characteristics of the RB-HEMTs in the present invention and the Schottky barrier RB-HEMTs in the prior art.

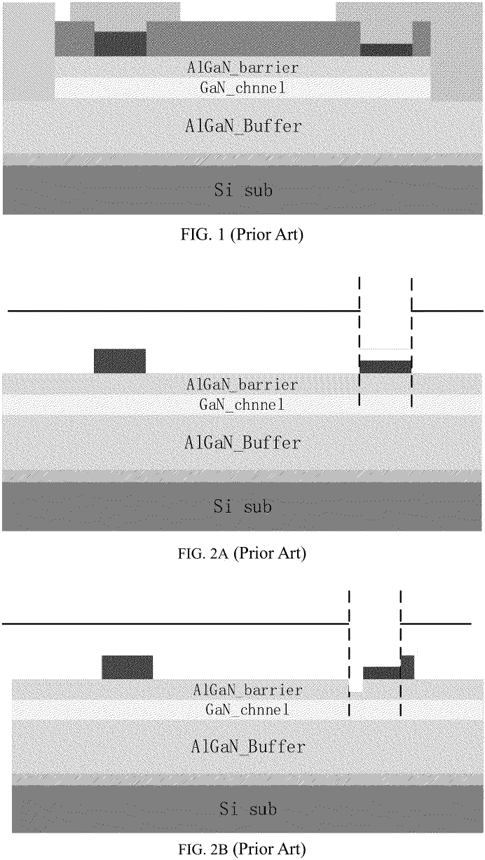

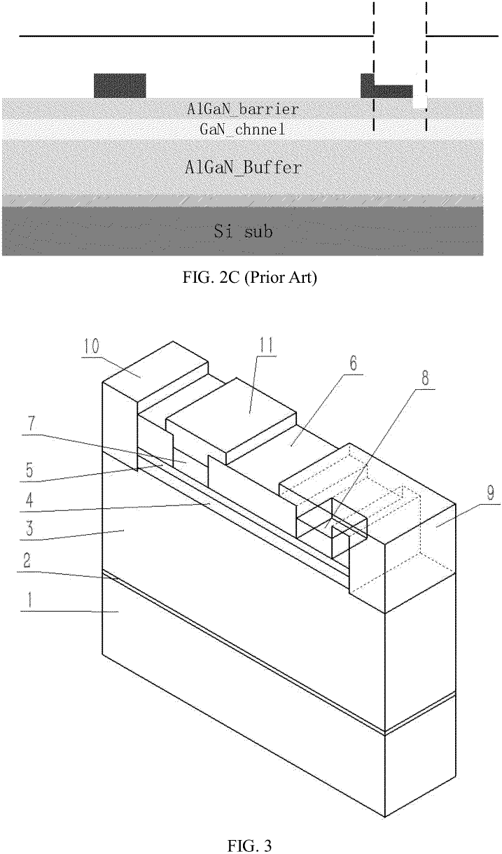

### DESCRIPTION OF THE EMBODIMENTS

The solution of the present invention will be further described below in conjunction with the drawings.

The present invention provides the RB-HEMTs include, sequentially stacked from bottom to top, a substrate 1, a nucleation layer 2, a buffer layer 3, a channel layer 4 and a barrier layer 5, wherein the channel layer 4 and the barrier layer 5 form a heterojunction structure; two ends of an upper surface of the barrier layer 5 are respectively provided with a first metal 9 embedded in the barrier layer 5 to form an ohmic contact and being a drain and a second metal 10 embedded in the barrier layer 5 to form an ohmic contact and being a source; characterized in that a first p-GaN structure 7 is provided on a side of the upper surface of the barrier layer 5 close to the second metal 10, a second p-GaN structure 8 is provided on a side of the upper surface of the barrier layer 5 close to the first metal 9, and a dielectric layer 6 is provided between the second metal 10 and the first p-GaN structure 7, between the first p-GaN structure 7 and the second p-GaN structure 8, and between the second p-GaN structure 8 and the first metal 9; the second p-GaN structure 8 includes one or more p-GaN structures arranged side-by-side in a device longitudinal direction, a length of the provided p-GaN structure in the device longitudinal direction is lower than a length of the barrier layer 5 in the device longitudinal direction, each of the p-GaN structures is isolated by the dielectric layer 6; a direction from the source to the drain is defined as a device lateral direction, and the device longitudinal direction is a third dimension direction perpendicular to both the device lateral direction and the device vertical direction; an upper surface of the first p-GaN structure 7 is provided with a third metal 11, the third metal 11 completely covering the upper surface of the first p-GaN structure 7 and extending to cover a part of an upper surface of the dielectric layer 6 along two sides in the device lateral direction, and the third metal 11 being a gate; and the first metal 9 extends in a direction pointing to the second metal 10 along an upper surface of the second p-GaN structure 8 to completely cover the upper surface of the second p-GaN structure 8 and the part of the upper surface of the dielectric layer 6.

Through the above steps, the electron gas in the channel is not completely depleted by the second p-GaN structure, so that a lower turn-on voltage and a stronger reverse blocking capability are achieved. Meanwhile, a thickness of the spaced p-GaN structure is the same as that of the gate p-GaN structure, which avoids the problem that the current recess etched GaN or recessed MIS hybrid drain technology needs additional process steps to etch the p-GaN layer and the barrier layer, and also overcomes the problem that the recess etched p-GaN cannot be completely aligned.

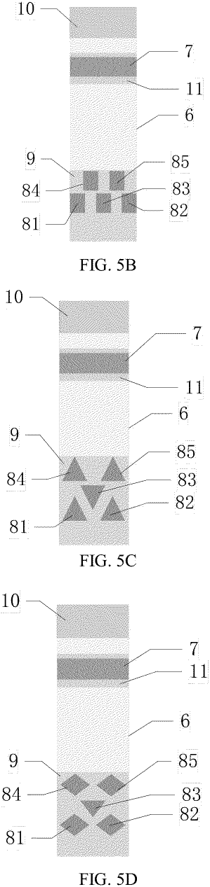

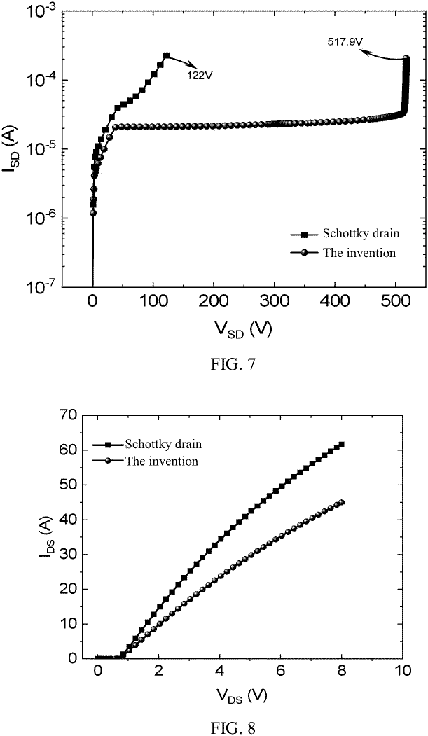

The shape, length, width and arrangement of the second p-GaN structure 8, referring to FIGS. 5A-5D, can be determined according to actual needs. That is to say, the second p-GaN structure 8 is arranged in many ways, regardless of its shape, length, width and arrangement, as long as its thickness is identical with the thickness of the gate p-GaN structure 7 and its width is less than the width of the barrier layer, it can be compatible with the conventional preparation process of GaN-based p-GaN enhancement-mode high electron migration transistor, thereby avoiding the problem that the current technology needs to etch the p-GaN layer or the barrier layer again, refer to FIG. 7. The GaN-based reverse blocking HEMT with strong reverse blocking capability and low forward turn-on voltage is prepared, which solves the problems in the prior art and achieves corresponding effects.

Referring to FIG. 3, a 3D structural diagram of a reverse blocking gallium nitride HEMT provided by the present invention includes:

a substrate 1, a nucleation layer 2 on the substrate 1, a buffer layer 3 on the nucleation layer 2, a channel layer 4 on the buffer layer 3, a barrier layer 5 on the channel layer 4, a source metal 10 on the barrier layer 5, a drain metal 9, a passivation layer 6, a gate p-GaN structure 7 and a spaced p-GaN structure composed of a second p-GaN structure 81, a third p-GaN structure 82 and a fourth p-GaN structure 83, and a gate metal 11 on the gate p-GaN structure.

Further, the source metal 10 and the drain metal are respectively located at two ends of the barrier layer 5. One end of the source metal 10 is embedded in the barrier layer 5 to form an ohmic contact. One end of the drain metal 9 is embedded in the barrier layer 5 to form a Schottky contact, the other end of the drain metal 9 forms the Schottky contact with a spaced second p-GaN structure 8 composed of the third p-GaN structure 81, the fourth p-GaN structure 82 and the fifth p-GaN structure 83. One end of the gate metal 11 forms a Schottky contact with the gate p-GaN structure 7 and the other end of the gate metal 11 extends toward the drain to form a field plate.

Specifically, the drain metal 9 and the spaced second p-GaN structure 8 composed of the third p-GaN structure 81, the fourth p-GaN structure 82, and the fifth p-GaN structure 83 form a hybrid drain structure together, and the two-dimensional electron gas below the spaced p-GaN structure is partially depleted by the spaced p-GaN structure. In reverse blocking, the electron gas below the spaced p-GaN structure is depleted under a lower bias voltage, thereby effectively blocking the current. While in the forward conduction, the electron gas below the spaced p-GaN structure is not completely depleted, therefore, the device has a relatively small forward conduction voltage.

Further, the substrate 1 is made of one or more of Si, SiC, sapphire and GaN.

Specifically, Si is of lower cost, while SiC has better thermal conductivity, also, the lattice constants of different substrates and the lattice mismatch degree of GaN materials are also very different, which have a direct impact on the overall wafer growth quality. Different substrate materials can be selected according to different requirements and application scenarios.

Further, the nucleation layer 2 is made of AlN, and a thickness of the AlN is in a range of 10 nm to 50 nm.

Further, the buffer layer 3 is made of AlGaN, and the Al, Ga and N components in the AlGaN are x, 1-x and 1, respectively, and the Al component x is in a range of 0 to 0.05.

Specifically, the buffer layer 3 is made of AlGaN, which can weaken the electron concentration between the barrier layer 5 and the channel layer 4 due to polarization, and deplete the electron gas concentration in the channel together with the gate p-GaN structure 7 and the second p-GaN structure 8, so that the device has better forward and reverse blocking capabilities, but too high Al composition will affect the forward conduction characteristics.

Further, the barrier layer 5 is made of AlGaN, and the Al, Ga and N components in the AlGaN are x, 1-x and 1, respectively, and the Al component x is in a range of 0.2 to 0.32.

Specifically, the barrier layer 5 and the channel layer 4 form a heterojunction structure. Under the spontaneous polarization caused by the crystal structure of the barrier layer 5 and the channel layer 4 and the piezoelectric polarization caused by the material strain, a two-dimensional potential trap is formed at the heterojunction interface, resulting in the accumulation of electrons at the interface to form the two-dimensional electron gas.

Further, a thickness of the second p-GaN structure 8 on the barrier layer 5 is identical with that of the gate p-GaN structure 7.

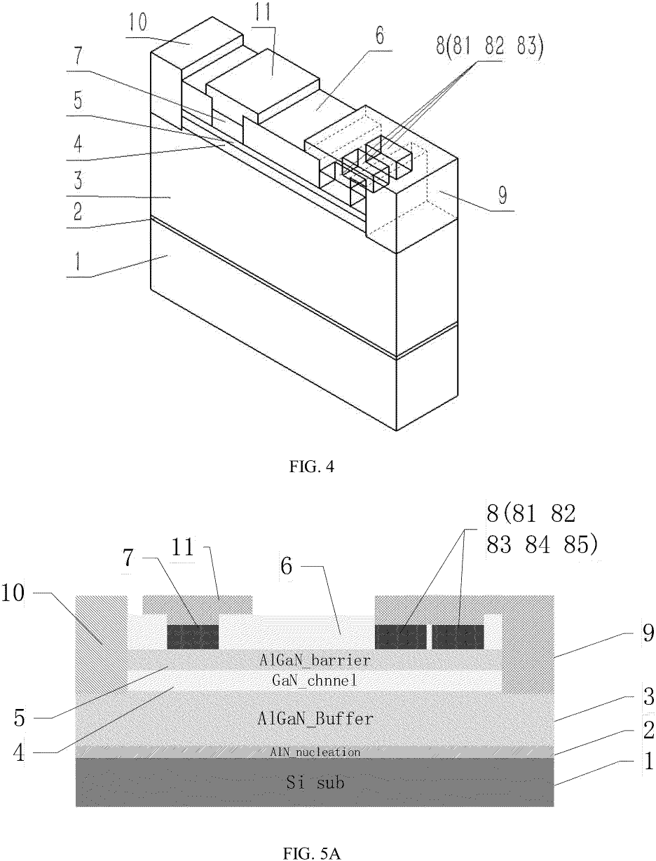

Specifically, referring to FIG. 4, during the process preparation for the gate p-GaN structure 7 and the spaced second p-GaN structure 8 composed of the third p-GaN structure 81, the fourth p-GaN structure 82 and the fifth p-GaN structure 83, all the p-GaN structures are formed in a one-step process, which ensures that the process is simple and feasible, and avoids the deviation problem existing in the secondary alignment during grinding.

Further, the second p-GaN structure 81, the third p-GaN structure 82, and the fourth p-GaN structure 83 have a width lower than a width of the barrier layer, and the width is a distance between a front surface and a back surface of the structure facing inward perpendicular to the plane of the drawing.

Specifically, the widths of the third p-GaN structure 81, the fourth p-GaN structure 82, and the fifth p-GaN structure 83 are lower than the width of the barrier layer, which ensures that the electron gas below the spaced p-GaN structure is not completely depleted in the forward conduction, and has better forward conduction characteristics. At the same time, the electron gas at the spaced p-GaN structure in reverse blocking can be quickly depleted, which effectively improves the blocking capability.

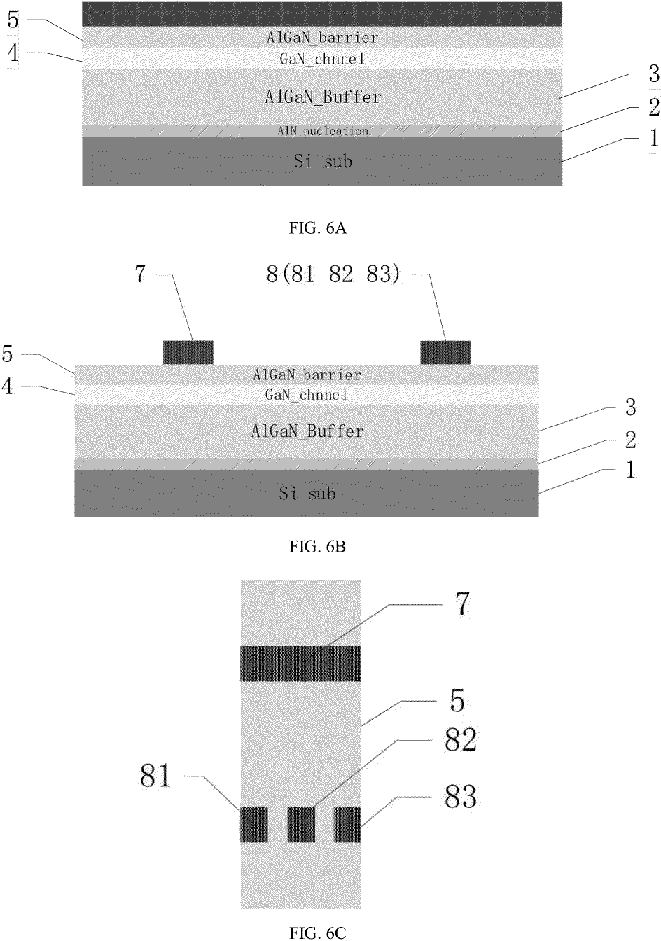

To sum up, under the hybrid drain structure composed of the second p-GaN structure and Schottky contact, the RB-HEMTs achieves high reverse blocking capability and low forward turn-on voltage at the same time. In addition, the drain spaced p-GaN structure and the gate p-GaN structure are formed synchronously, as shown in FIGS. 6A-6C, which simplifies the process steps and reduces the difficulty of device preparation. The present invention effectively avoids the problem that the existing p-GaN hybrid drain and recessed MIS hybrid drain technologies need multiple recess etching.

Referring to FIG. 4, the above-mentioned RB-HEMTs with spaced p-GaN structure is simulated by Sentaurus TCAD, resulting in FIG. 7. FIG. 7 is a comparison diagram of reverse blocking characteristics of the RB-HEMTs with the spaced p-GaN structure in the present invention and the conventional Schottky barrier RB-HEMTs As can be seen from the figure, a breakdown voltage of the conventional Schottky drain structure is only 122V, while the breakdown voltage of the present invention is as high as 517.9 V, indicating that the reverse blocking capability of the device is obviously improved.

Referring to FIG. 8, provided is a comparison diagram of forward output characteristics of the RB-HEMTs with the spaced p-GaN structure in the present invention and the conventional Schottky barrier RB-HEMTs. It can be seen that the device structure provided by the present invention has an extremely low turn-on voltage, which can almost reach the same forward turn-on voltage as the Schottky drain structure with low work function.

What is claimed is:

1. A reverse blocking gallium nitride high electron mobility transistor, comprising sequentially stacked from bottom to top, a substrate, a nucleation layer, a buffer layer, a channel layer and a barrier layer, wherein
the channel layer and the barrier layer form a heterojunction structure;
two ends of an upper surface of the barrier layer are respectively provided with a first metal and a second metal, wherein the first metal is embedded in the barrier layer to form a first ohmic contact and is a drain, and the second metal is embedded in the barrier layer to form a second ohmic contact and is a source;
a first p-GaN structure is provided on a first side of the upper surface of the barrier layer, wherein the first side of the upper surface of the barrier layer is adjacent to the second metal;
a second p-GaN structure is provided on a second side of the upper surface of the barrier layer, wherein the second side of the upper surface of the barrier layer is adjacent to the first metal;
a dielectric layer is provided between the second metal and the first p-GaN structure, between the first p-GaN structure and the second p-GaN structure, and between the second p-GaN structure and the first metal;
the second p-GaN structure comprises one or more p-GaN structures arranged side-by-side in a device longitudinal direction, wherein a length of the one or more p-GaN structures constituting the second p-GaN structure in the device longitudinal direction is smaller than a length of the barrier layer in the device longitudinal direction, the one or more p-GaN structures have a same thickness in a device vertical direction, and different p-GaN structures are isolated by the dielectric layer;
a direction from the source to the drain is defined as a device lateral direction, and the device longitudinal direction is a third dimension direction perpendicular to the device lateral direction and the device vertical direction;
an upper surface of the first p-GaN structure is provided with a third metal, wherein the third metal completely covers the upper surface of the first p-GaN structure and extends to cover a first part of an upper surface of the dielectric layer along two sides in the device lateral direction, and the third metal is a gate; and
the first metal extends in a direction pointing to the second metal along an upper surface of the second p-GaN structure to completely cover the upper surface of the second p-GaN structure and a second part of the upper surface of the dielectric layer.

2. The reverse blocking gallium nitride high electron mobility transistor according to claim 1, wherein the second p-GaN structure comprises a plurality of p-GaN structures, wherein in the plurality of p-GaN structures, a single row of p-GaN structures are distributed side-by-side along the device longitudinal direction or multiple rows of p-GaN structures are alternatively distributed side-by-side along the device longitudinal direction.

3. The reverse blocking gallium nitride high electron mobility transistor according to claim 1, wherein the second p-GaN structure comprises multiple p-GaN structures having a shape of one or a combination of rectangle, triangle, circle, ellipse and rhombus.
